(19) United States
(12) Patent Application Publication
(10) Pub. No.: US 2010/0096750 A1
(43) Pub. Date: Apr. 22, 2010

(54) Packaging substrate

(75) Inventors: Chao-Wen Shih, Sinfong Township (TW); Ying-Chih Chan, Sinfong Township (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/289,122

(22) Filed: Oct. 21, 2008

(51) Int. Cl. H01L 23/52

(52) U.S. Cl. 257/738; 257/E23.141

(57) ABSTRACT

A packaging substrate is disclosed, which comprises: a substrate body, wherein a surface thereof has a plurality of conductive pads and a solder mask disposed on the surface and having a plurality of openings to expose the conductive pads; dielectric rings disposed on the inner walls of the openings and extending to parts of the surface of the solder mask surrounding the openings; and metal bumps disposed in the openings and on the conductive pads exposed thereby, and combined with the dielectric rings.

### BACKGROUND OF THE INVENTION

1. Field of the Invention

The present invention relates to a packaging substrate. Particularly, the present invention relates to a packaging substrate, which can be applied to a packaging substrate exposed to high stress or a packaging substrate with thin gaps between metal bumps.

2. Description of Related Art

Customer demands of the electronics industry continue to evolve rapidly, and the main trends of electronic devices focus on multiple functions and high performance. Moreover, in order to satisfy the requirements for high integration and miniaturization, especially in the packaging of semiconductor devices, development of circuit boards with the maximum amount of active and passive components, and conductive wires has transferred from single-layered boards to multiple-layered boards. This means that a greater usable area on circuit board is available due to interlayer connection technology.

In a general process for manufacturing semiconductor devices, semiconductor chip carriers such as substrates or lead frames suitable for semiconductor devices are first provided by manufacturers. Then, the semiconductor chip carriers are processed by semiconductor chip attachment, wire bonding, encapsulating, implanting solder balls etc. for assembling semiconductor devices. In general, a conventional semiconductor package structure is made such that a semiconductor chip is mounted by its back surface on the top surface of the substrate, then the package structure is finished through wire bonding, or a semiconductor chip is mounted by the active surface thereof on the top surface of the substrate, thereby finishing a flip-chip package structure, followed by placing solder balls on the back surface of the substrate to provide electrical connections for an electronic device like a printed circuit board.

FIGS. 1A to 1F show the conventional method for fabricating a packaging substrate. As shown in FIG. 1A, the packaging substrate includes a substrate 10, and the surface of the substrate 10 has a plurality of conductive pads 11 and a solder mask 12, wherein the solder mask 12 has a plurality of openings 120 to expose the conductive pads 11. Furthermore, as shown in FIG. 1B, a conductive seed layer 13 is first formed on the surface of the substrate 10. As shown in FIG. 1C, a resist layer 14 is formed on the conductive seed layer 13, and the resist layer 14 has a plurality of resist-openings 140 corresponding to the openings 120 of the solder mask 12. Then, as shown in FIG. 1D, metal bumps 15 are formed in the resist-openings 140 by electroplating, wherein the material of the metal bumps 15 can be Cu etc. After that, as shown in FIG. 1E, the resist layer 14 and the conductive seed layer 13 covered thereunder is removed. Finally, as shown in FIG. 1F, solder bumps 16 are formed on the surfaces of the metal bumps 15.

In the aforementioned packaging substrate, the solder bumps 16 can be assembled with a chip by solder-reflowing as a flip-chip packaging. When the critical dimension such as line width of the packaging substrate is shortened, the strength of joints is reduced in relation to the reduction in the size of the joints. Hence, the strength of joints is insufficient to endure the stress between the chip and the substrate. Therefore, the phenomenon of joint breakage will become more serious. Furthermore, when the shapes of the openings of the solder mask are not good enough, or the surfaces of the conductive pads inside the openings are not clean enough, it is possible that the metal bumps cannot be assembled with the solder mask or the conductive pads well.

### SUMMARY OF THE INVENTION

The object of the present invention is to provide a packaging substrate, which can improve the adhesive strength between metal bumps and a solder mask. Hence, it is possible to apply the packaging substrate to a packaging substrate exposed to high stress or a packaging substrate with thin gaps between metal bumps.

To achieve the object, the present invention provides a packaging substrate, which comprises: a substrate body, wherein a surface thereof has a plurality of conductive pads, and a solder mask disposed on the surface and having a plurality of openings to expose the conductive pads; dielectric rings disposed on the inner walls of the openings, and extending to parts of the surface of the solder mask surrounding the openings; and metal bumps disposed in the openings and on the conductive pads exposed thereby, and combined with the dielectric rings.

The packaging substrate of the present invention can further comprise solder bumps disposed on the surfaces of the metal bumps.

According to the aforementioned packaging substrate, the packaging substrate can further comprise a metal adhesion layer disposed between the metal bumps and the solder bump.

The present invention further provides a method for manufacturing a packaging substrate, which comprises the following steps:

providing a substrate body, wherein a surface thereof has a plurality of conductive pads, and a solder mask formed on the surface and having a plurality of openings to expose the conductive pads; forming dielectric rings on the inner walls of the openings, wherein the dielectric rings extend to parts of the surface of the solder mask surrounding the openings; forming a conductive seed layer on the surfaces of the solder mask, the dielectric rings, and the exposed parts of the conductive pads; forming a resist layer on the surface of the conductive seed layer, and forming a plurality of resist-openings corresponding to the openings of the solder mask; forming metal bumps in the resist-openings by electroplating; and removing the resist layer and the conductive seed layer covered thereunder.

The aforementioned method can further comprise a step of forming solder bumps on the surfaces of the metal bumps.

The aforementioned method can further comprise a step of forming a metal adhesion layer on the surface of the metal bumps before forming the solder bump.

According to the aforementioned method, the dielectric rings can be formed through laminating a photosensitive dielectric layer on the surface of the solder mask, and then exposing and developing the photosensitive dielectric layer. Also, the dielectric rings can be formed through coating the surface of the solder mask with a photosensitive dielectric layer, and then exposing and developing the photosensitive dielectric layer.

Other objects, advantages, and novel features of the invention will become more apparent from the following detailed description when taken in conjunction with the accompanying drawings.

### BRIEF DESCRIPTION OF THE DRAWINGS

FIGS. 1A to 1F are cross-sectional views for illustrating a process for manufacturing a conventional packaging substrate; and

FIGS. 2A to 2H are cross-sectional views for illustrating a process for manufacturing a packaging substrate according to an embodiment of the present invention.

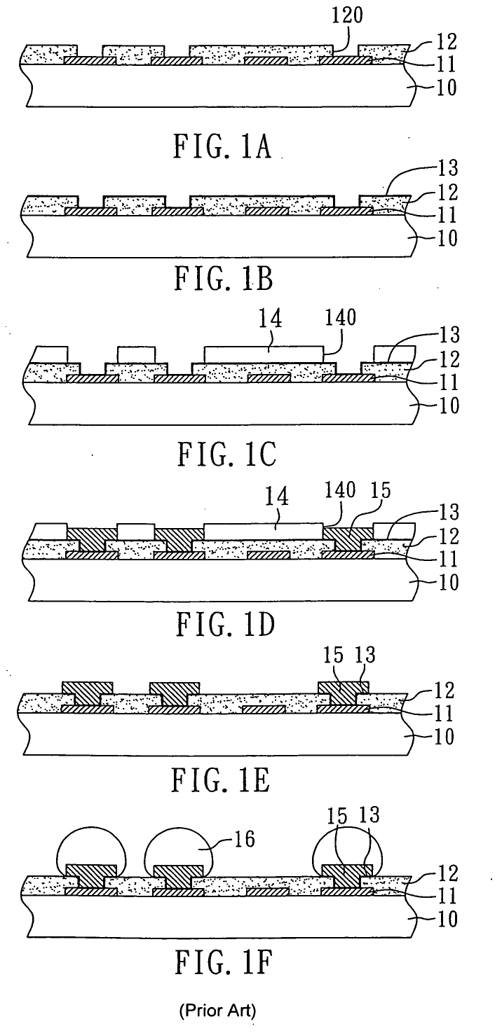

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

### Embodiment for Manufacture

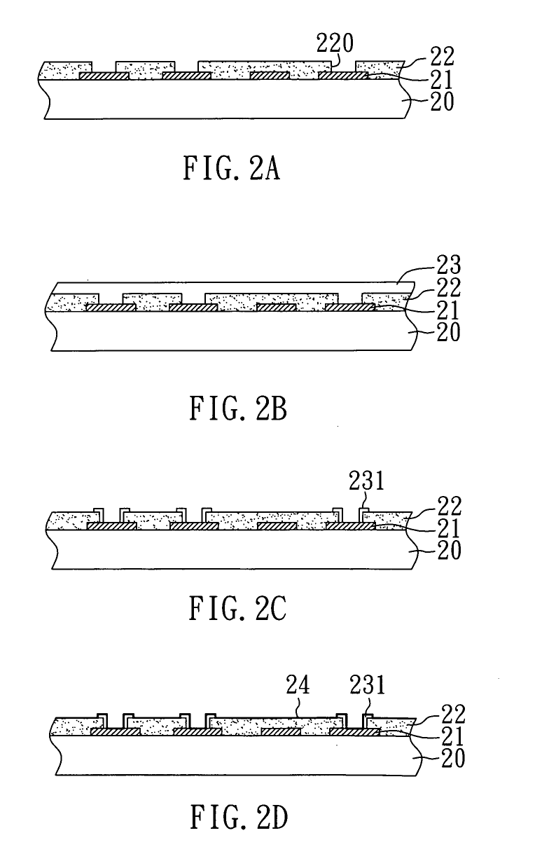

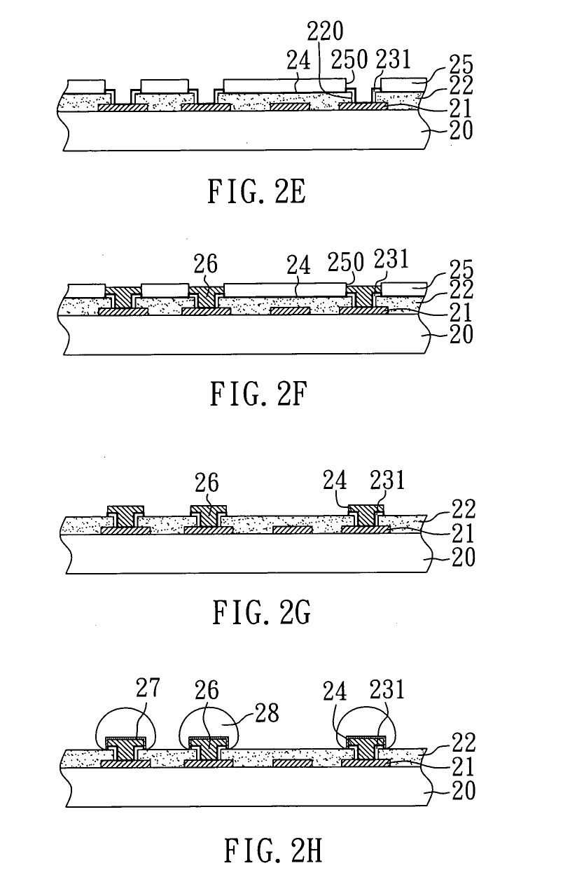

First, with reference to FIG. 2A, a substrate body 20 is provided, wherein a surface of the substrate body 20 has a plurality of conductive pads 21, and a solder mask 22 disposed on the surface and having a plurality of openings 220 to expose the conductive pads 21. Here, the material of the conductive pads 21 is selected from the group consisting of Cu, Sn, Ni, Cr, Ti, Cu/Cr alloy, and Sn/Pb alloy.

With reference to FIG. 2B, a photosensitive dielectric layer 23 is laminated on the surface of the substrate body 20, or the surface of the substrate body 20 is coated with a photosensitive dielectric layer 23. Then, with reference to FIG. 2C, dielectric rings 231 are formed on the inner walls of the openings 220, wherein the dielectric rings 231 extend to parts of the surface of the solder mask 22 surrounding the openings 220 through exposing and developing the photosensitive dielectric layer 23.

In the present embodiment, the material of the dielectric rings may be a photosensitive dielectric material, which can be selected from the group consisting of benzocylobuthene (BCB), Bismaleimide triazine (BT), Liquid Crystal Polymer, Poly-imide (PI), Poly(phenylene ether), Poly(tetra-fluoroethylene), Aramide, epoxy resin, and glass fiber.

With reference to FIG. 2D, a conductive seed layer 24 is formed on the surfaces of the solder mask 22, the dielectric rings 231, and the exposed parts of the conductive pads 21 by electroless plating.

Further, with reference to FIG. 2E, a resist layer 25 is formed on the surface of the conductive seed layer 24, and a plurality of resist-openings 250 are formed corresponding to the openings 220 of the solder mask 22. Herein, the resist layer 25 can be a dry film or a liquid photoresist film. In the present embodiment, the resist layer 25 is a dry film.

Then, with reference to FIG. 2F, metal bumps 26 are formed in the resist-openings 250 by electroplating. The material of the metal bumps 26 is selected from the group consisting of Cu, Ni, Cr, Ti, Cu/Cr alloy, and Sn/Pb alloy. In the present embodiment, the material of the metal bumps 26 is Cu. Finally, with reference to FIG. 2F, the resist layer 25, and the conductive seed layer 24 covered thereunder are removed.

In the aforementioned method, with reference to FIG. 2H, solder bumps 28 are further formed on the surfaces of the metal bumps 26. In addition, a metal adhesion layer 27 is further formed on the surface of the metal bumps 26 before the solder bump 28 is formed. Herein, the metal adhesion layer 27 is formed by physical deposition (such as sputtering or evaporation), or chemical deposition (such as electroless plating). Besides, the material of the metal adhesion layer 27 is selected from the group consisting of Sn, Ag, Ni, Au, Cr/Ti, Ni/Au, Ni/Pd, and Ni/Pd/Au. In the present embodiment, the material of the metal adhesion layer 27 is Sn.

### Embodiment of Packaging Substrate

As shown in FIG. 2G, the present invention provides a packaging substrate, which comprises: a substrate body 20 wherein a surface thereof has a plurality of conductive pads 21, and a solder mask 22 disposed on the surface thereof and having a plurality of openings 220 to expose the conductive pads 21; dielectric rings 231 disposed on the inner walls of the openings 220, and extending to parts of the surface of the solder mask 22 surrounding the openings 20; and metal bumps 26 disposed in the openings 220 and on the conductive pads 21 exposed thereby, and combined with the dielectric rings 231.

With reference to FIG. 2H, the aforementioned packaging substrate further comprises solder bumps 28 formed on the surfaces of the metal bumps 26. In addition, the aforementioned packaging substrate further comprises a metal adhesion layer 27 formed between the metal bumps 26 and the solder bump 28. Herein, the material of the metal bumps 26 is selected from the group consisting of Cu, Ni, Cr, Ti, Cu/Cr alloy, and Sn/Pb alloy. In the present embodiment, the material of the metal bumps 26 is Cu. Besides, the material of the metal adhesion layer 27 is selected from the group consisting of Sn, Ag, Ni, Au, Cr/Ti, Ni/Au, Ni/Pd, and Ni/Pd/Au. In the present embodiment, the material of the metal adhesion layer 27 is Sn.

In conclusion, the packaging substrate of the present invention can enhance the adhesive strength between metal bumps and a solder mask by dielectric rings formed with a photosensitive dielectric material, wherein the dielectric rings are formed between the metal bumps and the solder mask. Hence, the problem of poor adhesive strength between the metal bumps and the solder mask in the prior art can be improved. Therefore, the packaging substrate of the present invention can conquer high stress imposed on joints between a packaging substrate and a semiconductor chip.

Although the present invention has been explained in relation to its preferred embodiment, it is to be understood that many other possible modifications and variations can be made without departing from the scope of the invention as hereinafter claimed.

1. A packaging substrate, comprising:
a substrate body, wherein a surface thereof has a plurality of conductive pads, and a solder mask disposed on the surface and having a plurality of openings to expose the conductive pads;
dielectric rings disposed on the inner walls of the openings, and extending to parts of the surface of the solder mask surrounding the openings; and
copper bumps disposed in the openings and on the conductive pads exposed thereby, and jointed to the dielectric rings.

2. The packaging substrate as claimed in claim 1, further comprising solder bumps disposed on the surfaces of the copper bumps.

3. The packaging substrate as claimed in claim 2, further comprising a metal adhesion layer disposed between the copper bumps and the solder bump.

4. The packaging substrate as claimed in claim 3, wherein the material of the metal adhesion layer is selected from the group consisting of Sn, Ag, Ni, Au, Cr/Ti, Ni/Au, Ni/Pd, and Ni/Pd/Au.

5. (canceled)

6. The packaging substrate as claimed in claim 1, wherein the material of the dielectric rings is a photosensitive dielectric material.
